(19) United States
(12) Patent Application Publication
(10) Pub. No.: US 2007/0013263 A1
(43) Pub. Date: Jan. 18, 2007

(54) Electrical isolation for ultrasound transducer stacks

(75) Inventors: Nelson H. Oliver, Sunnyvale, CA (US); Worth B. Walters, Cupertino, CA (US)

Correspondence Address: SIEMENS CORPORATION;INTELLECTUAL PROPERTY DEPARTMENT, 170 WOOD AVENUE SOUTH, ISELIN, NJ, 08830, US

(73) Assignee: Siemens Medical Solutions USA, Inc.

(21) Appl. No.: 11/147,036

(22) Filed: Jun. 6, 2005

(51) Int. Cl. H01L 41/00

(52) U.S. Cl. 310/311

(57) ABSTRACT

One or more conductors within a transducer or element are anodized and/or electrochemically etched for electrical isolation. Anodization allows for simultaneous creation of many insulation layers on a selective basis. Electrochemical etching allows for simultaneous creation of many electrode gaps on a selective basis, which can be later filled with insulating material such as epoxy. Conductors may then be plated over the anodized material for interconnecting other conductors or electrodes together.

### BACKGROUND

The present invention relates to electrical isolation in ultrasound transducer stacks. In particular, conductors in an ultrasound transducer are separated from each other by electrical isolation.

Elements of ultrasound transducers include two or more electrodes. For example, electrodes on opposite sides of transducer material are used for applying electrical signals to the transducer or receiving electrical signals generated by the transducer. The transducer material electrically insulates the two electrodes from each other. However, conductors routing signals to and from the electrodes may require further separation or isolation.

For electrical impedance mismatches with transmit or receive circuitry, elements of the transducer array may include a plurality of layers of transducer material. Each layer of transducer material is separated by an electrode. Every other or every third electrode within the stack of transducer material may be electrically connected. Routing conductors for a single element to different electrode layers is difficult and time consuming. Where the elements are used in a multi-dimensional transducer array, access to individual elements for routing or interconnecting different electrodes of each element is limited. Using deposition, ablation or other step wise treatments may limit the ability for cost effective scalable fabrication.

### BRIEF SUMMARY

By way of introduction, the preferred embodiments described below include transducers, methods of insulating conductors in transducers and improvements for electrical isolation in ultrasound transducer stacks. One or more conductors within a transducer or element are anodized for electrical isolation. Anodization allows for simultaneous creation of many insulation layers on a selective basis. Conductors may then be plated over the anodization material for interconnecting other conductors or electrodes together. In an alternative embodiment, one or more conductors may be electrochemically etched back to provide isolation without an anodized insulation layer.

In a first aspect, a method is provided for limiting electrical interconnection of components of an ultrasound transducer stack. At least first and second components are stacked. At least the first component is anodized.

In a second aspect, a transducer is provided for transducing between electrical and ultrasound energies. Two conductive components are positioned adjacent to each other in the transducer. An anodized insulator is between the two conductive components.

In a third aspect, an improvement is provided in a transducer array of a plurality of elements for transducing between electrical and ultrasound energies. One of the elements has at least a first electrode between two layers of piezoelectric material. The improvement includes an anodized insulator connected with the electrode.

In a fourth aspect, a method is provided for limiting electrical interconnection of components of an ultrasound transducer stack. At least and second components are stacked. At least the first component is selectively etched by an electrochemical means, such that the first component is isolated from a third component of the transducer. Any insulation is optional.

The present invention is defined by the following claims, and nothing in this section should be taken as a limitation on those claims. Further aspects and advantages of the invention are discussed below in conjunction with the preferred embodiments.

### BRIEF DESCRIPTION OF THE DRAWINGS

The components and the figures are not necessarily to scale, emphasis instead being placed upon illustrating the principles of the invention. Moreover, in the figures, like reference numerals designate corresponding parts throughout the different views.

FIG. 1 is a perspective view of one embodiment of a 3-3 mode transducer array;

FIG. 2 is a cross-sectional view of one embodiment of an element in a 3-3 mode transducer array;

FIG. 3 is a flow chart diagram showing one embodiment of a method for electrically insulating components of an ultrasound transducer.

FIG. 4 is a cross-sectional view of another embodiment of an element in a 3-1 mode transducer array; and

FIG. 5 is a flow chart diagram showing one embodiment of a method for electrically isolating components of a 3-1 mode ultrasound transducer element without insulation.

### DETAILED DESCRIPTION OF THE DRAWINGS AND PRESENTLY PREFERRED EMBODIMENTS

Anodization is used for forming complete or partial electrical isolation in elements. Anodization allows the simultaneous creation of many insulator layers that selectively cover internal stack electrodes or other conductors. Anodizing operates only on positively charged metals. Oxide insulation forms on electrodes held at an anodic potential while leaving other metals unaffected. During electrochemical oxidation, the positively charged conductor sacrifices some mass to form the insulation layer. The exposed portions of the positively charged metal form the electrical insulator. Other conductors may then be formed over the electrical insulator for interconnecting different electrodes.

Any conductive component of a transducer may be anodized. For example, metalized matching layers, conductors for Z-axis or other routing within a backing block, conductive bridges, electrodes used adjacent to transducer material, grounding planes, flex circuits or other conductive materials are anodized. Since only particular metals may be anodized, a coating of a suitable metal such as aluminum, titanium, copper, tantalum, zinc, magnesium, silver, or cadmium may be applied such as by sputtering to an arbitrary conductive component to permit anodization. The anodization is performed prior to or after stacking with the transducer stack. Transducer manufacturing techniques now known or later developed may be used with anodization.

FIG. 1 shows one embodiment of a 3-3 mode transducer 10 for transducing between electrical and ultrasound energies. The transducer 10 includes a plurality of elements 12. As shown in FIG. 1, the elements 12 are arranged in a two-dimensional array. The elements 12 are distributed along azimuth (y) and elevation (z) dimensions. Other multi-dimensional arrays, such as 1.25, 1.5 or 1.75D arrays may be used. In yet other embodiments, a single element or one-dimensional array of elements 12 is provided.

The transducer 10 includes anodized material for one or more elements 12, for other materials common to multiple elements 12, or for both materials common to multiple elements 12 and individual elements 12. For example, each element 12 includes an arrangement of at least two different conductive components. An anodized insulator separates or is between the two conductive components, such as between signal traces or other conductive materials for two different electrodes of the same element.

The transducer 10 shown in FIG. 1 includes a plurality of layers 14 of transducer material in each element 12. Each of the layers 14 is sandwiched between two electrodes. Two, three or more layers 14 are provided for the multi-layer structure. In alternative embodiments, the elements 12 have a single layer 14 of transducer material. Transducer material includes single crystal piezoelectrics, other piezoelectrics, composites, microelectromechanical devices or other now known or later developed structures for transducing between electrical and acoustic energies.

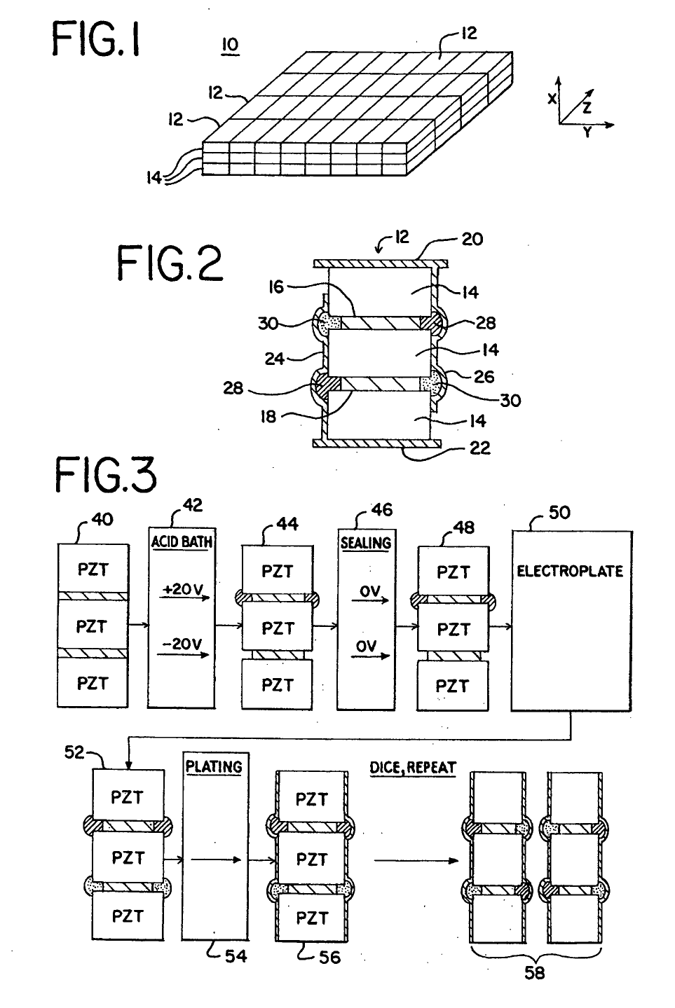

FIG. 2 shows one embodiment of an element 12 with three layers 14 of transducer material. The element 12 includes three layers 14 of transducer material, two or more conductive components (16-26), anodized material 28, and electroplated material 30. Additional, different or fewer components may be provided. For example, the element 12 is provided without the electroplated material 30 or with a fewer or greater number of layers 14 of transducer material and associated electrodes 16-22.

Some electrodes 16 and 18 are positioned between the layers 14 of transducer material. The electrodes 16, 18 are aluminum, titanium, copper, silver, cadmium, magnesium or other oxidizable conductive material. A single electrode or plurality of electrodes is positioned between each layer 14 of transducer material. The electrodes 16, 18 are deposited or stacked and bonded to the layers 14 for asperity contact. In other embodiments, the electrodes 16, 18 are formed through sintering and lamination. The conductive components 20 and 22 are electrodes formed in a similar manner on the top of the uppermost layer 14 and the bottom of the lowermost layer 14. Alternatively, the electrical components 20 and/or 22 are formed from flexible circuits or other conductors positioned adjacent to the transducer material. For example, the upper conductive component 20 is a sheet of metal laid over a plurality of elements 12 or is a conductive matching layer. As another example, the lower conductive component 22 is an electrode and associated Z-axis conductor provided in a backing block.

Additional conductive components 24, 26 are formed on the sides of the element 12. The sides of the element 12 are generally perpendicular to the electrodes 16, 18 between the layers 14. The conductive components 24, 26 are deposited metal layers. Alternatively, wire bonds or other jumpers are provided. Any conductive material may be used. The conductors 24, 26 are provided on opposite sides of the element 12, but may be positioned adjacent to each other on a same side or on adjacent sides of the element 12. The conductors 24, 26 electrically interconnect different sets of the electrodes 16, 18, 20, 22. For example, the conductor 24 on one side connects the lowermost signal electrode 22 with the electrode 16 between the upper two layers 14 of transducer material, and the opposite conductor 26 connects the upper electrode or ground plane 20 to the electrode 18 between the lowermost two layers 14 of transducer material. The conductors 24, 26 are deposited, etched or otherwise formed to provide the desired electrical interconnections. For example, the conductor 24 on one side avoids connection with the ground plane 20, and the conductor 26 on another side avoids connection with the signal electrode 22. Alternatively, the ground plane 20 and the signal electrode 22 are formed or provided with insulation such that electrical contact with the conductors 24, 26 is avoided as desired without patterning or etching of the conductors 24, 26.

The anodized insulators 28 are positioned between conductive components, such as between the electrode 18 and the conductor 24 or between the electrode 16 and the conductor 26. The anodized insulator 28 is oxidized material formed on, in, from or adjacent to the electrodes 16, 18 or other conductor. The anodized insulators 28 also include a sealed anodic coating. Alternatively, no anodic coating is provided. The anodized material electrically insulates the conductive components from each other. While shown with a bump on the side of the element 12 and extending into a gap between layers 14, the anodized insulator 28 may have other shapes, such as a flat, recessed or etched shape. The anodized insulators 28 are formed, in part, between the layers 14 or entirely on the side and not between the layers 14.

The electroplated material 30 is an electrically conductive material, such as copper, nickel, or silver. The electroplated material 30 forms a bump, ridge, plate or other structure for increasing electrical connectivity of the conductors 24, 26 to desired electrodes 16, 18. For example and as shown in FIG. 2, the electroplated material 30 forms a bump structure that extends away from the transducer material 14 as well as in between the layers 14. In alternative embodiments, the electroplated material 30 is entirely between the layers 14 or not between the layers 14.

The same electrode 16 has both electroplated material 30 and anodized insulators 28. For example, the electrode 16 has an electroplated material 30 from on one exposed surface on one side of the element 12, and anodized insulator 28 formed on another exposed surface on another side of the element 12. Alternatively, a given electrode 16, 18 is associated with or connects with only anodized insulators 28 or electroplated material 30. In yet other alternative embodiments, an exposed surface of one or more of the electrodes 16, 18 is free of either electroplated material 30 or anodized insulator 28.

FIG. 3 shows one embodiment of a method for electrically insulating components of an ultrasound transducer stack. The method results in the transducer or transducer elements described above for FIG. 1 or 2 or other transducer structure. Additional, different or fewer acts may be performed, such as skipping the electroplating act 50 and/or the dicing and repeating act 58. The acts are performed in the same or different order than shown, such as performing the electroplating act 50 prior to the anodizing acts 42 and 46.

FIG. 3 is directed towards anodizing in a multilayer transducer element. The anodizing electrically isolates conductors used for connecting every other electrode within a stack of electrodes and transducer material layers together. Electrodes not to be connected to a conductor are isolated using anodization. In alternative embodiments, the anodization electrically isolates other conductive components of the transducer, such as isolating one component of one element from a different conductor of a different element. Anodizing may electrically isolate other conductors within a same element in yet other alternative embodiments.

In act 40, components of a transducer are stacked together. Components include transducer material, matching layer, backing block, electrodes, grounding planes, signal conductors, flex circuits, lenses, and/or other now known or later developed transducer component. Two or more of the components are stacked together, such as stacking one or more layers of transducer material, associated electrodes and grounding planes and flex circuits, a backing block and one or more matching layers. As represented in the act 40 shown in FIG. 3, one example includes three layers of piezoelectric transducer material stacked with one or more electrodes between each of the pairs of layers.

In one embodiment, the stack is for a single element. In other embodiments, the stack is for a plurality of elements, such as providing an elongated shaped stack of transducer components to be diced into a one-dimensional array. In yet another example, a plurality of slabs of material are stacked for dicing into a multi-dimensional transducer array.

In one embodiment, the dicing is performed after any anodization or etching steps, such as acts 42 and 46. In another embodiment, the stack components are diced along a first dimension, such as dicing along an azimuth or an elevation dimension. The spacing between kerfs formed by the dicing is for a single element, two elements, or three or more elements. The dicing forms all kerfs along a given dimension or does not form all of the kerfs to be formed for an operable transducer along the given dimension. For example, every other kerf extends along the dimension. The kerfs extend along an orthogonal dimension. For example, kerfs are cut along an azimuth dimension and have an elevation spacing corresponding to separating every other element rather than each element.

In an optional act, exposed portions of the electrodes between transducer layers are etched after dicing and prior to anodizing. The etching is performed using electrical current, chemicals or mechanical devices, such as a grinder or dicing saw. For example, electrically activated chemicals operable to slowly remove material of the electrodes and not the transducer layers are applied. The etching results in a recess or void between each of the transducer layers by the exposed electrodes. The recess may be used to better electrically isolate electrodes from conductors formed on the sides, and may supplant the anodizing step entirely in cases where the electrode gap need not be bridged with an electrically conducting layer.

In act 42, one or more components of the transducer stack are anodized. For example, an exposed portion of one of the electrodes between transducer layers is anodized. Aluminum, titanium or other metal conductor is connected to a potential source. For example, one of the electrodes is connected to a positive 20 volt potential, but other voltage potentials may be provided. For conductors not to be anodized, the conductors are maintained at a zero or negative voltage potential. By providing a voltage difference between the anode and cathode, such as graphite, material for anodization is selectively attacked and converted to oxide. In one embodiment, each of the layers is stacked so as to provide a graduated or stepped structure. The uppermost structures have a narrower width. A probe or other electrical conductor is then connected with the desired step or structure for anodizing by inserting the probe within the kerfs from above. Other structures for applying electrical potential to the desired electrodes may be provided.

While applying the desired voltages, the stack is immersed in an acidic solution. For example, sulfuric, oxalic, phosphoric, boric, chromic or other acid solutions are used. The solution is of any concentration, such as about 15 percent. The length of immersion is minutes, but greater or lesser lengths may be provided. The electrodes which are not to be insulated are protected from oxidation by maintaining them at the cathode potential during acidic immersion. The electrically isolating material is formed within each of the kerfs along the exposed portions of positively charged conductors. Anodization grows an insulation layer by conversion of the metal itself, resulting in a swelled hydrous oxide. The anodization material is formed to one or more microns of thickness. Alternatively, a thinner or thicker insulation layer is anodized. The anodized material electrically isolates one conductor from an existing or later formed conductor on the transducer stack. After the acid bath in act 42, anodized material is on the positively charged electrode as shown in 44. The negatively or cathode charged electrode is free of anodized material.

In act 46, the anodized material is sealed. Any sealing process may be used, such as immersion of the transducer stack in heated water or exposure to a warm solution of metal salts, such as nickel acetate. The sealing drives off excess water and closes pores in the coating. The transducer stack shown at 48 includes a sealed or coated anodized material.

In act 50, the transducer stack is electroplated. For example, exposed portions of electrodes are electroplated. A potential is applied to electrodes to be electroplated. For example, a negative potential is applied. Other conductors are maintained at a ground or positive potential. The transducer stack is immersed in a solution for electroplating. The electroplating builds up conductive material on exposed portions of any negatively charged conductors. For example, the electrode between the lower two layers of transducer material is negatively charged and immersed. As shown at 52, electroplated material forms knobs or other structures at the exposed portions of the negatively charged electrode. The anodizing in acts 42 and electroplating in act 50 create conductive and electrically insulating materials for different electrodes or other conductors to be interconnected.

In act 54, a conductor is plated along the side of the stacked layers of transducer material and over the anodized and/or electroplated portions of the electrodes. An electroless metal plating, such as silver, copper or nickel, is deposited along the sides within the kerfs. The anodized coating insulates the upper electrode within the stack from the metal coating on the sides. The anodized coating also provides for mechanical continuity for connection of conductors. The electrically insulating material electrically separates the plated conductor from the electrode. The electroplated material provides a larger surface area for the conductor to connect with the lower or other electrode as shown at 56. In the multidimensional array embodiment discussed above, the plating or conductive material is plated in a plurality of kerfs. In an alternative embodiment, a conductive filler such as silver-epoxy fills the kerfs, establishing the desired electrical interconnects between electroplated electrodes.

In embodiments with kerfs, the kerfs are filled. For example, two or more kerfs formed for a multi-dimensional array are filled with an epoxy or other non-conductive material. The filling acts to prevent further anodizing, electroplating or other alterations to the conductor connections formed in later steps.

In embodiments with kerfs, such as multi-dimensional arrays, additional kerfs are formed in act 58, and the anodization act 42, electroplating act 50, sealing act 46 and/or plating act 54 are repeated for the additional kerfs. For example, the original kerfs are even number kerfs and the kerfs in act 58 are odd numbered kerfs. The odd number kerfs are spaced apart along the same dimensions as the even number kerfs. These additional kerfs create two-element-wide slabs along the elevation dimension. The anodizing, and/or electroplating are then performed in the additional kerfs. The original kerfs that are filled with epoxy or other substance remain unchanged. Additional anodic coating and/or electroplating are formed in the new kerfs. Conductive material is then electrolessly plated in the new kerfs. As shown in act 58, two elements are formed with conductors on each side. Electroplating material provides for electrical connection of the conductors to some of the electrodes. Other conductors are isolated from those same electrodes by the anodized material.

For a multi-dimensional array, transverse kerfs are formed. Dicing along the transverse dimension forms the array of elements. The kerfs electrically and mechanically isolate different elements within the array. Any further processing, such as further kerf filling, stacking with matching layers, stacking with backing layers or other transducer manufacturing processes are then performed.

For each element, the electrically isolating anodized material prevents interconnection of some conductors. For example, connections are provided for every other electrode to a same conductor on one side of the element and the other electrodes on another side. A multi-layer structure may then be used for transmit or receive operations with ultrasound energy. Similarly, conductive electroplating material may provide for a more consistent connection of electrodes to conductors. The conductors for each element are formed in sequential processes. Alternatively, the conductors and the electrically insulating material are formed at a same time on different sides of a same element. Different layers of each element operate in conjunction with the same electrical signals to transduce between electrical and acoustic energies.

In one embodiment, the potential applied to one or more electrodes in either the anodizing or electroplating is provided through signal electrodes, such as a flex circuit formed on the top and/or bottom of the transducer layer stack. For example, with the multi-dimensional array, flex circuits include bus connections between or along an elevation dimension. The bus connections are removed by the transverse dicing, providing electrical isolation. Similarly, buses may be formed between adjacent pairs of elements. Forming kerfs or dicing removes the bus connections after they have been used for applying potential to two or more elements in the same way.

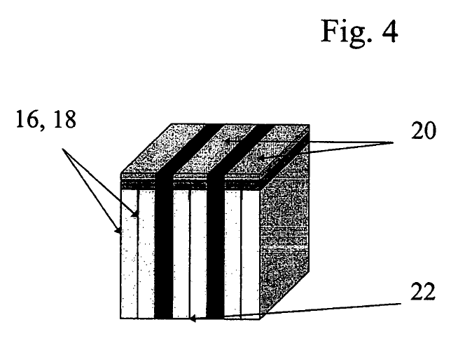

To avoid transverse electrical field operation, each element is made as thin as possible in a range or Z-axis dimension and as wide as possible along the azimuth and/or elevation dimensions given a frequency of operation. Alternatively, a 3-1 excitation mode is used, such as disclosed in U.S. Pat. No. ______ (application Ser. No. 11/051,089 (attorney reference number 2004P01995 US01)), the disclosure of which is incorporated herein by reference. FIG. 4 shows an example 3-1 mode transducer stack. Layers of transducer material are separated by electrodes 16, 18, such as Pd/Ag electrodes. The layers of transducer material and electrodes 16, 18 are stacked along an azimuth or elevation dimension rather than a range dimension. Acoustic energy is transmitted and/or received from a face of the transducer along the matching layers 20. The electric field is transverse, such as along the azimuth or elevation dimensions.

The anodizing discussed herein is used to insulate the electrodes 16, 18 from connections with the flexible circuit 22 or the ground/conductive matching layer 20. Alternatively, the electrodes 16, 18 are isolated, where appropriate, by electrochemical etching. Since the electrodes 16, 18 connect with the ground/matching layer 20 or the flex circuit 22 without depositing further conductors (e.g., 24, 26), the anodized insulator may not be needed to support the further conductors. Instead, the electrodes 16, 18 are electrochemically etched at locations to avoid undesired electrical connections. By etching, the electrodes 16, 18 are removed or recessed at desired locations of exposure. When the ground/matching layer 20 and the flex circuit 22 are stacked, the recess prevents electrical connectin and air, gas or bonding material electrically insulate the electrodes 16, 18.

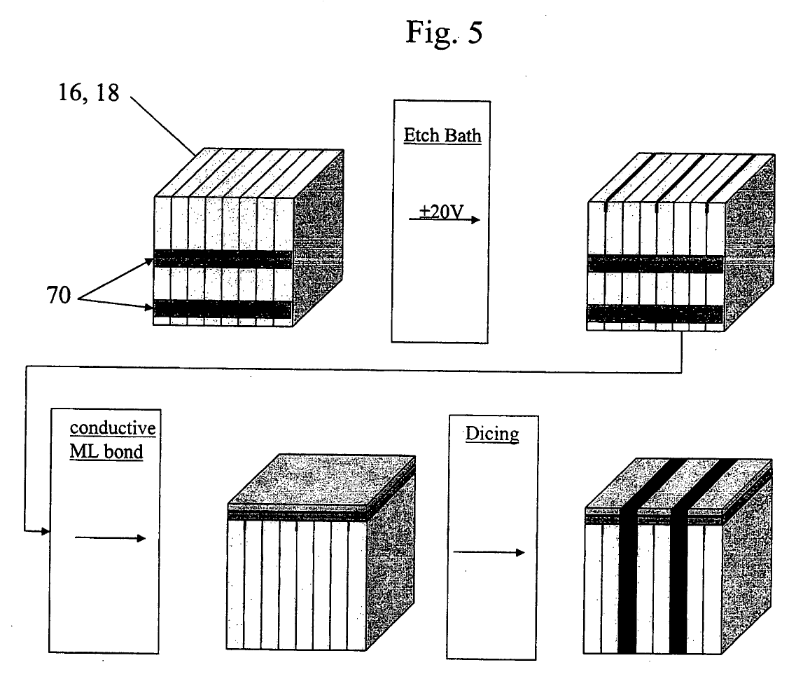

FIG. 5 shows a method for electrically insulating components of an ultrasound transducer stack. Etching is used for isolation. Layers of transducer material and electrodes 16, 18 are stacked. Busbars 70 interconnect desired electrodes for electrochemical etching. The etching electrically separates conductors used for connecting every third or other electrodes within the stack of electrodes and transducer material layers together. Electrodes not to be connected to a conductor are isolated during the matching-layer bonding stage, wherein the etched gap fills with bond epoxy. In alternative embodiments, the etching electrically isolates other conductive components of the transducer, such as isolating one component of one element from a different conductor of a different element. Etching may electrically isolate other conductors within a same element in yet other alternative embodiments.

While the invention has been described above by reference to various embodiments, it should be understood that many changes and modifications can be made without departing from the scope of the invention. It is therefore intended that the foregoing detailed description be regarded as illustrative rather than limiting, and that it be understood that it is the following claims, including all equivalents, that are intended to define the spirit and scope of this invention.

I(We) claim:

1. A method for electrically insulating components of an ultrasound transducer stack, the method comprising:
stacking at least first and second components of the transducer stack; and
anodizing at least the first component.

2. The method of claim 1 wherein anodizing comprises electrically isolating the first component from the second component, the first and second components being electrically conductive.

3. The method of claim 1 wherein stacking comprises stacking two or more layers of piezoelectric material with an electrode between the two or more layers of piezoelectric material, and wherein anodizing comprises anodizing an exposed portion of the electrode.

4. The method of claim 3 further comprising:
plating a conductor along a side of the stacked two or more layers and over an anodized portion of the electrode.

5. The method of claim 4 further comprising:
electroplating an exposed portion of an additional electrode of the stacked two or more layers prior to plating, the conductor electrically connecting with electroplated material on the exposed portion.

6. The method of claim 1 wherein anodizing comprises applying a voltage to the first component and immersing the first component in an acid solution.

7. The method of claim 1 wherein stacking comprises stacking two or more layers of piezoelectric material with an electrode between the two or more layers;
further comprising:
dicing the stacked two or more layers and electrode along a first dimension, at least first and second kerfs spaced apart along a different second dimension being formed from the dicing;
wherein anodizing comprises forming electrically isolating material in the at least first and second kerfs adjacent the electrode.

8. The method of claim 7 further comprising:
etching an exposed portion of the electrode after dicing and prior to anodizing.

9. The method of claim 7 further comprising:
plating conductive material in the at least first and second kerfs, the conductive material being over the electrically isolating material, the electrically isolating material electrically separating the conductive material from the electrode.

10. The method of claim 9 further comprising:
dicing the stacked two or more layers and electrode along the first dimension after the anodizing, at least third and forth kerfs spaced apart along the different second dimension being formed from the dicing after anodizing, the stacked two or more layers and electrode between the first and third, third and second, and second and fourth being an element width.

11. The method of claim 10 further comprising:
filling the first and second kerfs;
anodizing after the filling, the anodizing forming electrically isolating material in the third and fourth kerfs adjacent the electrode;
plating conductive material in the third and fourth kerfs, the conductive material being over the electrically isolating material in the third and fourth kerfs, the electrically isolating material electrically separating the conductive material from the electrode; and
dicing along the second dimension, the dicing along the second dimension forming a multi-dimensional array of elements in conjunction with the first, second, third and fourth kerfs;
wherein the conductive material and electrically isolating material in the first and second kerfs electrically connects different layers of each element than the conductive material and electrically isolation material of the third and fourth kerfs.

12. A transducer for transducing between electrical and ultrasound energies, the transducer comprising:
a first conductive component;
a second conductive component adjacent the first conductive component in the transducer; and
an anodized insulator between the first and second conductive components.

13. The transducer of claim 12 wherein the first conductive component is an electrode between two layers of transducer material.

14. The transducer of claim 13 wherein the second conductive component is a conductive material on a first side of the two layers of transducer material, the anodized insulator electrically isolating the electrode from the conductive material.

15. The transducer of claim 14 wherein the two layers of transducer material comprise first and second layers of transducer material, the electrode being between the first and second layers;
further comprising:
an additional electrode between the second layer and a third layer of transducer material, the additional electrode electrically connected with the conductive material on the first side;
wherein an additional conductor on a different, second side electrically connects with the electrode and is electrically isolated from the additional electrode by an additional anodized insulator.

16. The transducer of claim 12 wherein the anodized insulator comprises oxidized material formed on the electrode.

17. The transducer of claim 14 wherein the two layers of transducer material comprise first and second layers of transducer material, the electrode being between the first and second layers;
further comprising:
an additional electrode between the second layer and a third layer of transducer material; and
an electroplated bump on the additional electrode, the additional electrode electrically connected with the conductive material through the electroplated bump.

18. The transducer of claim 12 wherein the transducer comprises a multi-dimensional array of elements, each element comprising arrangements of the first and second conductive components and the anodized insulator.

19. In a transducer array of a plurality of elements for transducing between electrical and ultrasound energies, a first element of the plurality of elements having at least a first electrode between two layers of piezoelectric material, an improvement comprising:
an anodized insulator connected with the first electrode.

20. The improvement of claim 19 further comprising a conductor connected with at least a second electrode of the first element, the anodized insulator electrically insulating the first electrode from the conductor.

21. The improvement of claim 20 wherein the conductor is on a side of the first element generally perpendicular to the first electrode.

22. The improvement of claim 19 wherein the transducer array is a multi-dimensional array, each element of the multi-dimensional array having electrodes electrically insulated with anodized material, the electrodes being between two or more layers of piezoelectric material.

23. The improvement of claim 19 further comprising:
an electroplated material connected with the first electrode at a different portion than the anodized insulator.

24. A method for electrically insulating components of an ultrasound transducer stack, the method comprising:
stacking at least first and second conductive components of the transducer stack; and
etching at least the first component, the etching separating the second conductive component as previously or later stacked adjacent to the first conductive component.

25. The method of claim 24 wherein etching comprises electrochemically etching.

26. The method of claim 24 wherein stacking comprises stacking piezoelectric layers of transducer material with the first conductive component, the first conductive component being an electrode.

27. The method of claim 24 wherein stacking the second conductive component comprises stacking a ground layer, a conductive matching layer, a flexible circuit or combinations thereof.

28. The method of claim 24 wherein the transducer stack comprises a transducer operable in a 3-1 mode.
